(19) United States
(12) Patent Application Publication
(10) Pub. No.: US 2025/0149480 A1
(43) Pub. Date: May 8, 2025

(54) SEMICONDUCTOR PACKAGE

(71) Applicant: SAMSUNG ELECTRONICS CO., LTD., SUWON-SI (KR)

(72) Inventors: Wonhee LEE, Suwon-si (KR); Yun-Rae CHO, Suwon-si (KR)

(21) Appl. No.: 18/804,574

(22) Filed: Aug. 14, 2024

(30) Foreign Application Priority Data
Nov. 6, 2023 (KR) 10-2023-0151703
Feb. 7, 2024 (KR) 10-2024-0018835

(51) Int. Cl. H01L 23/00; H01L 23/31; H01L 23/48; H01L 25/18; H10B 80/00

(52) U.S. Cl. CPC H01L 24/06; H01L 23/481; H01L 24/08; H01L 24/09; H01L 25/18; H01L 23/3107; H01L 24/05; H01L 2224/05647; H01L 2224/0603; H01L 2224/06133; H01L 2224/06137; H01L 2224/08146; H01L 2224/09181; H10B 80/00

(57) ABSTRACT

A semiconductor package includes: a first semiconductor chip; and a second semiconductor chip connected to the first semiconductor chip, wherein the first semiconductor chip includes: a first semiconductor layer; a first through electrode penetrating the first semiconductor layer; and a first connection pad part positioned on the first semiconductor layer and including a plurality of first connection pads connected to the first through electrode, wherein the second semiconductor chip includes: a second semiconductor layer; a second through electrode penetrating the second semiconductor layer; and a second connection pad part positioned on the second semiconductor layer to face the first connection pad part and including a plurality of second connection pads connected to the second through electrode, wherein the plurality of first connection pads is in contact with the plurality of second connection pads, respectively.

### CROSS-REFERENCE TO RELATED APPLICATION

This application claims priority under 35 U.S.C. § 119 to Korean Patent Application No. 10-2023-0151703 filed in the Korean Intellectual Property Office on Nov. 6, 2023, and Korean Patent Application No. 10-2024-0018835 filed in the Korean Intellectual Property Office on Feb. 7, 2024, the disclosures of which are incorporated by reference herein in their entireties.

### TECHNICAL FIELD

The present inventive concept relates to a semiconductor package.

### DISCUSSION OF THE RELATED

When bonding a plurality of semiconductor chips to each other or a semiconductor chip and a substrate to each other in a semiconductor package process, as a pitch between bonding pads narrows, a process that directly bonds pads to each other without solder balls or solder bumps is currently under development.

A hybrid bonding uses a property of bonding between the same materials to bond the plurality of semiconductor chips to each other or the semiconductor chip and the substrate to each other, and according to the hybrid bonding, an input/output (I/O) with a fine pitch may be formed.

In addition, when the semiconductor chips are bonded in the hybrid bonding process, a defect (e.g., a non-wet defect), in which the pads that are included in the bonding parts of each of two semiconductor chips are not physically and electrically connected to each other, may occur.

### SUMMARY

According to an embodiment of the present inventive concept, a semiconductor package includes: a first semiconductor chip; and a second semiconductor chip connected to the first semiconductor chip, wherein the first semiconductor chip includes: a first semiconductor layer; a first through electrode penetrating the first semiconductor layer; and a first connection pad part positioned on the first semiconductor layer and including a plurality of first connection pads connected to the first through electrode, wherein the second semiconductor chip includes: a second semiconductor layer; a second through electrode penetrating the second semiconductor layer; and a second connection pad part positioned on the second semiconductor layer to face the first connection pad part and including a plurality of second connection pads connected to the second through electrode, wherein the plurality of first connection pads is in contact with the plurality of second connection pads, respectively.

According to an embodiment of the present inventive concept, a semiconductor package includes: a first semiconductor chip; and a second semiconductor chip connected to the first semiconductor chip, wherein the first semiconductor chip includes: a first semiconductor layer; a first through electrode penetrating the first semiconductor layer in a thickness direction; a first connection pad part positioned on one surface of the first semiconductor layer and including a plurality of first connection pads connected to the first through electrode; a lower wire structure positioned between the first connection pad part and the first through electrode, and connecting the first connection pads to the first through electrode; and a first insulating layer at least partially surrounding the first connection pads, wherein the second semiconductor chip includes: a second semiconductor layer; a second through electrode penetrating the second semiconductor layer; a second connection pad part positioned on one surface of the second semiconductor layer to face the first connection pad part and including a plurality of second connection pads connected to the second through electrode; an upper wire structure positioned on the second through electrode; an upper conductive pattern positioned on the upper wire structure and having an upper surface in contact with the plurality of second connection pads; and a second insulating layer at least partially surrounding the second connection pads and having an upper surface in contact with the lower surface of the first insulating layer, wherein the plurality of first connection pads is in contact with the plurality of second connection pads, respectively, and the interface of the first insulating layer and the second insulating layer is on the same plane as the interface of the first connection pad and the second connection pad.

According to an embodiment of the present inventive concept, a semiconductor package includes: an interposer; a logic die placed on the interposer; and a high bandwidth memory placed on the interposer, wherein the high bandwidth memory includes: a first semiconductor chip and a second semiconductor chip connected to the first semiconductor chip, wherein the first semiconductor chip includes: a first semiconductor layer: a first through electrode penetrating the first semiconductor layer; and a first connection pad part including a plurality of first connection pads positioned on one surface of the first semiconductor layer and connected to the first through electrode, wherein the second semiconductor chip includes: a second semiconductor layer; a second through electrode penetrating the second semiconductor layer; and a second connection pad part including a plurality of second connection pads positioned on one surface of the second semiconductor layer and connected to the second through electrode, wherein the plurality of first connection pads is in contact with the plurality of second connection pads, respectively.

### BRIEF DESCRIPTION OF THE DRAWINGS

FIG. 1 is a cross-sectional view illustrating a semiconductor package according to an embodiment of the present inventive concept.

FIG. 2 is an enlarged cross-sectional view of a bonding part of a semiconductor package according to an embodiment of the present inventive concept.

FIG. 3 is an enlarged top plan view of a bonding part of a semiconductor package according to an embodiment of the present inventive concept.

FIG. 4 is an enlarged top plan view of a bonding part of a semiconductor package according to an embodiment of the present inventive concept.

FIG. 5 is an enlarged cross-sectional view of a bonding part of a semiconductor package according to an embodiment of the present inventive concept.

FIG. 6 is an enlarged top plan view of a bonding part of a semiconductor package according to an embodiment of the present inventive concept.

FIG. 7 is an enlarged top plan view of a bonding part of a semiconductor package according to an embodiment of the present inventive concept.

FIG. 8 is an enlarged cross-sectional view of a bonding part of a semiconductor package according to an embodiment of the present inventive concept.

FIG. 9 is an enlarged top plan view of a bonding part of a semiconductor package according to an embodiment of the present inventive concept.

FIG. 10 is an enlarged top plan view of a bonding part of a semiconductor package according to an embodiment of the present inventive concept.

FIG. 11 is an enlarged cross-sectional view of a bonding part of a semiconductor package according to an embodiment of the present inventive concept.

FIG. 12 is an enlarged top plan view of a bonding part of a semiconductor package according to an embodiment of the present inventive concept.

FIG. 13 is an enlarged top plan view of a bonding part of a semiconductor package according to an embodiment of the present inventive concept.

FIG. 14 is an enlarged top plan view of a bonding part of a semiconductor package according to an embodiment of the present inventive concept.

FIG. 15 is an enlarged top plan view of a bonding part of a semiconductor package according to an embodiment of the present inventive concept.

FIG. 16 is an enlarged cross-sectional view of a bonding part of a semiconductor package according to an embodiment of the present inventive concept.

FIG. 17 is a cross-sectional view showing a 2.5D semiconductor package including a bonding structure according to an embodiment of the present inventive concept.

FIG. 18 is a cross-sectional view showing a 3D semiconductor package including a bonding structure according to an embodiment of the present inventive concept.

### DETAILED DESCRIPTION OF THE EMBODIMENTS

Embodiments of the present inventive concept will be described more fully hereinafter with reference to the accompanying drawings. As those skilled in the art would realize, the described embodiments may be modified in various different ways, all without departing from the spirit or scope of the present inventive concept.

Like reference numerals designate like elements throughout the specification, and thus, redundant descriptions may be omitted or briefly discussed.

In the drawings, various thicknesses, lengths, and angles are shown and while the arrangement shown does indeed represent an embodiment of the present inventive concept, it is to be understood that modifications of the various thicknesses, lengths, and angles may be possible within the spirit and scope of the present inventive concept and the present inventive concept is not necessarily limited to the particular thicknesses, lengths, and angles shown.

It will be understood that when an element such as a layer, film, region, or substrate is referred to as being “on” another element, it can be directly on the other element or intervening elements may also be present. In contrast, when an element is referred to as being “directly on” another element, there are no intervening elements present therebetween. Further, in the specification, the word “on” or “above” means positioning on or below the object portion, but does not essentially mean positioning on the upper side of the object portion based on a gravity direction.

Further, in the specification, the phrase “in a plan view” means when an object portion is viewed from above, and the phrase “in a cross-section” means when a cross-section taken by vertically cutting an object portion is viewed from the side.

Hereinafter, a semiconductor package according to an embodiment of the present inventive concept is described as follows.

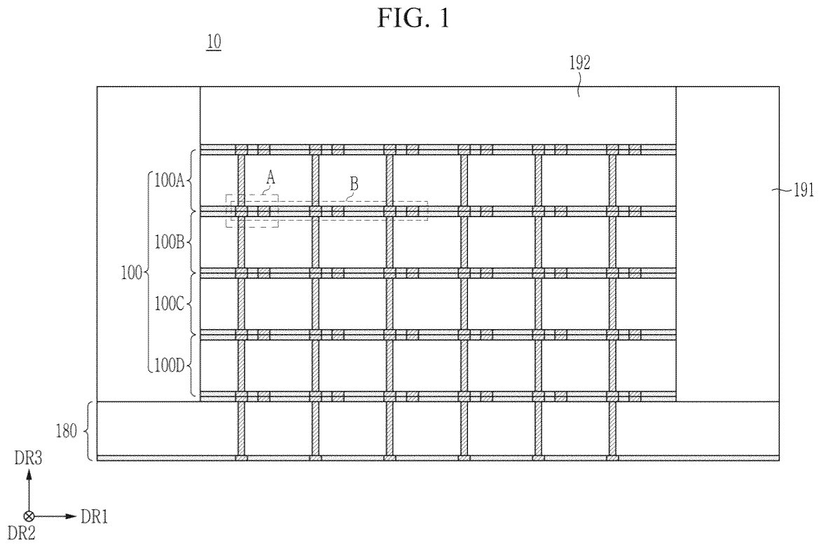

FIG. 1 is a cross-sectional view showing a semiconductor package according to an embodiment of the present inventive concept.

Referring to FIG. 1, a semiconductor package 10 may include a semiconductor chip stacking structure 100, a bottom die 180 positioned under the semiconductor chip stacking structure 100, a molding material 191 positioned on both sides of the semiconductor chip stacking structure 100, and a dummy silicon layer 192 positioned on the semiconductor chip stacking structure 100.

The semiconductor chip stacking structure 100 may have a structure in which a plurality of semiconductor chips 100A to100D are stacked in one direction (e.g., a third direction DR3) on each other. The semiconductor chip stacking structure 100 may be placed on the bottom die 180. In an embodiment of the present inventive concept, the bottom die 180 may have a width in the first direction DR1 that is larger than a width of the semiconductor chip stacking structure 100.

In an embodiment of the present inventive concept, the semiconductor package 10 may include a high bandwidth memory (HBM). Each of the plurality of semiconductor chips 100A to 100D stacked to form the semiconductor chip stacking structure 100 may be a memory chip (e.g., a DRAM), and the bottom die 180 may be a buffer die. In the embodiment below, the semiconductor package 10 will be described as an example that includes a high bandwidth memory, but the embodiment is not limited to the high bandwidth memory.

The bottom die 180 may be positioned below the semiconductor chip stacking structure 100. The semiconductor chip stacking structure 100 and the bottom die 180 may be bonded to each other by a hybrid bonding. Each of the semiconductor chips 100A to 100D included in the semiconductor chip stacking structure 100 may be bonded to each other by a hybrid bonding. The hybrid bonding may be performed by the bonding part included in each semiconductor chip 100A to 100D, or the bottom die 180. The bonding part may be a part where the semiconductor chips 100A to 100D are in contact with each other when the plurality of semiconductor chips 100A to 100D are stacked on each other and connected to each other. In addition, the bonding part may be a part where the semiconductor chip and the bottom die 180 are in contact with each other when one of the plurality of semiconductor chips 100A to 100D and the bottom die 180 are connected to each other.

The hybrid bonding includes bonding two devices by a method of fusing the same materials of two devices by using bonding properties of the same materials. For example, in the bonding part, it may mean that two devices are bonded to each other through a metal-metal bonding and a non-metal-non-metal bonding. According to the hybrid bonding, an input/output (I/O) with a fine pitch may be formed. For example, when two semiconductor chips are bonded to each other, the bonding part of each semiconductor chip may include one or more connection pads and an insulating layer adjacent to the connection pad. At this time, in the bonding part, the connection pads may be bonded to the connection pads, and the insulating layers may be bonded to the insulating layers.

In the embodiment, each of the semiconductor chips 100A and 100B included in the semiconductor package 10 may include two or more connection pads connected to one through electrode.

The molding material 191 may be placed on both sides of the semiconductor chip stacking structure 100. The molding material 191 may be placed above the bottom die 180. The molding material 191 may serve to protect and insulate the semiconductor chip stacking structure 100. In an embodiment of the present inventive concept, the molding material 191 may be formed of a thermosetting resin, such as an epoxy resin. In an embodiment of the present inventive concept, the molding material 191 may be an epoxy molding compound (EMC). In an embodiment of the present inventive concept, the molding process with the molding material 191 may include a compression molding or a transfer molding process.

The dummy silicon layer 192 may be positioned on the semiconductor chip stacking structure 100. The dummy silicon layer 192 may be a configuration to radiate heat that is generated within the high bandwidth memory to the outside. The dummy silicon layer 192 may include, for example, a crystalline silicon. The thermal conductivity of silicon may have a value greater than that of the molding material 191. Heat generated in the high bandwidth memory may be effectively dissipated by the dummy silicon layer 192 including silicon.

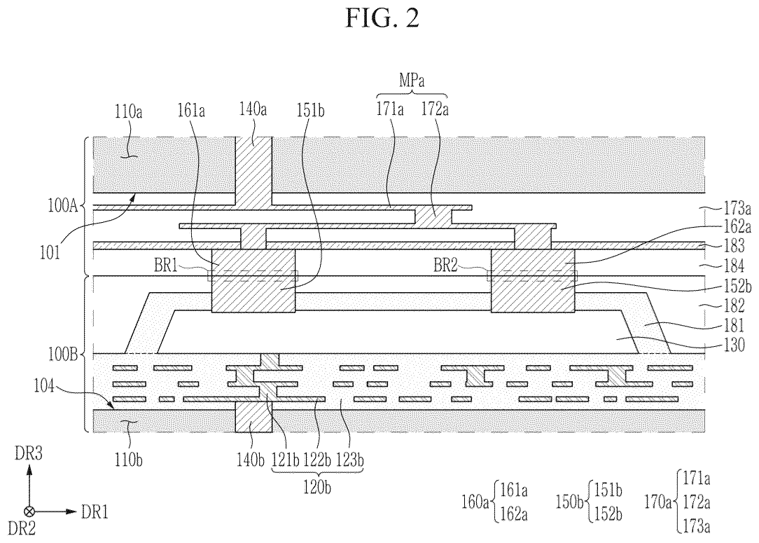

FIG. 2 is a cross-sectional view illustrating a semiconductor package according to an embodiment of the present inventive concept. For example, FIG. 2 is the enlarged cross-sectional view of the region A in FIG. 1. FIG. 2 may only show some regions of the first semiconductor chip 100A and some regions of the second semiconductor chip 100B described with reference to FIG. 1. For example, some regions of the first semiconductor chip 100A that are shown in FIG. 2 may be a lower region of the first semiconductor chip 100A. Some regions of the second semiconductor chip 100B shown in FIG. 2 may be the upper region of the second semiconductor chip 100B. For example, FIG. 2 may represent the bonding part where the lower surface of the first semiconductor chip 100A and the upper surface of the second semiconductor chip 100B are bonded to each other.

Referring to FIG. 2, the semiconductor package according to an embodiment of the present inventive concept may include a first semiconductor chip 100A and a second semiconductor chip 100B connected to the first semiconductor chip 100A. Referring to FIG. 2, the first semiconductor chip 100A and the second semiconductor chip 100B may be connected to each other in the vertical direction. The first semiconductor chip 100A may include a first semiconductor layer 110a, a first through electrode 140a penetrating the first semiconductor layer 110a, and a plurality of first connection pads 161a and 162a connected to the first through electrode 140a. The second semiconductor chip 100B may include a second semiconductor layer 110b, a second through electrode 140b penetrating the second semiconductor layer 110b, and a plurality of second connection pads 151b and 152b connected to the second through electrode 140b.

The first semiconductor layer 110a may include, for example, a semiconductor element such as silicon (Si) or germanium (Ge), or may include a compound semiconductor such as silicon carbide (SiC), gallium arsenide (GaAs), indium arsenide (InAs), or indium phosphide (InP). The first semiconductor layer 110a may include a first surface 101 and a second surface facing the first surface 101. The first surface 101 may be a surface that is opposite the second surface in the vertical direction. For example, the first surface 101 may be the lower surface of the first semiconductor layer 110a, and the second surface may be the upper surface of the first semiconductor layer 110a. The first surface 101 of the first semiconductor layer 110a may be formed as a plane parallel to the first direction DR1 and the second direction DR2 that intersects the first direction DR1.

The first through electrode 140a may penetrate the first semiconductor layer 110a in the third direction DR3. The third direction DR3 may be a direction perpendicular to the first direction DR1 and the second direction DR2. At least a portion of the sidewall of the first through electrode 140a may be surrounded by the first semiconductor layer 110a. For example, at least a portion of the sidewall of the first through electrode 140a may be in direct contact with the first semiconductor layer 110a. Referring to FIG. 2, the first through electrode 140a may have a region protruded beyond the first surface 101 to the opposite direction of the third direction DR3. In this case, the protruded region, as shown in FIG. 2, may extend inside a first lower wire structure 170a, which will be described later. In this case, the lower surface of the first through electrode 140a may be positioned at a lower height than the first surface 101. However, the present inventive concept is not limited thereto, and the lower surface of the first through electrode 140a may have the same height as that of the first surface 101. For example, the lower surface of the first through electrode 140a may be aligned on the same plane as that of the first surface 101.

For example, the first through electrode 140a may be formed by drilling thousands of fine holes that vertically penetrate the first semiconductor layer 110a, filling the holes with a conductive material, and connecting them to each other as an electrode. At this time, holes penetrating the first semiconductor layer 110a may be formed by a deep etching. In an embodiment of the present inventive concept, holes penetrating the first semiconductor layer 110a may be formed by a laser. In an embodiment of the present inventive concept, the holes may be filled with a conductive material by an electrolytic plating. In an embodiment of the present inventive concept, the first through electrode 140a may include at least one of tungsten (W), aluminum (Al), copper (Cu), and alloys thereof.

A plurality of first connection pads 161a and 162a may be positioned on the lower surface of the first through electrode 140a. In FIG. 2, two first connection pads 161a and 162a are shown, but the number of the connection pads connected to one first through electrode 140a is not limited thereto. On the first surface 101, the plurality of first connection pads 161a and 162a connected to one first through electrode 140a may constitute one first connection pad part 160a. The first connection pads 161a and 162a may be commonly connected to the first through electrode 140a. The first connection pads 161a and 162a may be electrically connected to the lower surface of the first through electrode 140a. Referring to FIG. 2, the first lower wire structure 170a, which will be described later, may be positioned between the first connection pads 161a and 162a and the lower surface of the first through electrode 140a. The first connection pads 161a and 162a may be electrically connected to the first through electrode 140a through lower wire patterns MPa included in the first lower wire structure 170a. The first connection pads 161a and 162a may be connected with the second connection pads 151b and 152b. In the embodiment, the lower surface of at least one of the plurality of first connection pads 161a and 162a may be in contact with the upper surface of at least one of the plurality of second connection pads 151b and 152b. In the embodiment, the lower surface of another one of the plurality of first connection pads 161a and 162a may be in contact with the upper surface of another one of the plurality of second connection pads 151b and 152b. Referring to FIG. 2, the lower surface of each of the first connection pads 161a and 162a may be in contact with the upper surface of each of the second connection pads 151b and 152b. In an embodiment of the present inventive concept, the interfaces where the first connection pads 161a and 162a and the second connection pads 151b and 152b respectively contact each other may be aligned on the same plane as each other.

In an embodiment of the present inventive concept, the widths of the first connection pads 161a and 162a along the first direction DR1 may be substantially equal to each other. In an embodiment of the present inventive concept, the width of the first connection pads 161a and 162a along the first direction DR1 may be substantially equal to the width of the second connection pads 151b and 152b along the first direction DR1. However, the present inventive concept is not limited thereto, and the width of the first connection pads 161a and 162a along the first direction DR1 may be smaller or larger than the width of the second connection pads 151b and 152b along the first direction DR1. The first connection pads 161a and 162a may have the substantially the same thickness as each other. The first connection pads 161a and 162a may have the upper surfaces positioned at substantially the same height. For example, the upper surfaces of the first connection pads 161a and 162a may be substantially aligned on the same plane. The first connection pads 161a and 162a may have the lower surfaces positioned at substantially the same height as each other. For example, the lower surfaces of the first connection pads 161a and 162a may be aligned substantially on the same plane.

The first connection pads 161a and 162a may include a conductive material. For example, the first connection pads 161a and 162a may include at least one of a metal, a metal alloy, a conductive metal nitride, a conductive metal carbide, a conductive metal oxide, conductive metal carbonitride and/or two-dimensional material (2D material). The metal may include at least one of titanium (Ti), tantalum (Ta), tungsten (W), nickel (Ni), cobalt (Co), platinum (Pt), copper (Cu), and/or aluminum (Al). In an embodiment of the present inventive concept, each of the first connection pads 161a and 162a included in one first connection pad part 160a may include the same conductive material as each other. For example, the first connection pads 161a and 162a may include copper (Cu). However, the present inventive concept is not limited thereto, the first connection pads 161a and 162a may each include different types of conductive materials from each other.

The first connection pads 161a and 162a may be connected to the second connection pads 151b and 152b, respectively. Accordingly, the first connection pads 161a and 162a may provide a passage of an electrical signal flowing from the first semiconductor chip 100A to the second semiconductor chip 100B, or from the second semiconductor chip 100B to the first semiconductor chip 100A.

The second semiconductor layer 110b may include, for example, a semiconductor element such as silicon (Si) or germanium (Ge), or may include a compound semiconductor such as silicon carbide (SiC), gallium arsenide (GaAs), indium arsenide (InAs), or indium phosphide (InP). The second semiconductor layer 110b may include a third surface and a fourth surface 104 facing the third surface. The fourth surface 104 may be a surface that is opposite to the third surface in the vertical direction. For example, the third surface may be the lower surface of the second semiconductor layer 110b, and the fourth surface 104 may be the upper surface of the second semiconductor layer 110b. The fourth surface 104 of the second semiconductor layer 110b may be formed as a plane parallel to the first direction DR1 and the second direction DR2 that intersects the first direction DR1. The second semiconductor layer 110b may include, for example, a semiconductor element such as silicon (Si) or germanium (Ge), or may include a compound semiconductor such as silicon carbide (SiC), gallium arsenide (GaAs), indium arsenide (InAs), or indium phosphide (InP). The upper region of the second semiconductor layer 110b may have a silicon on insulator (SOI) structure. The second semiconductor layer 110b may include an active region, for example, an impurity doped well, or an impurity doped structure. The second semiconductor layer 110b may include various element isolation structures such as a shallow trench isolation (STI) structure. The second semiconductor layer 110b may include one or more individual semiconductor devices (e.g., transistors) in positions adjacent to a second upper wire structure 120b, which will be described later.

The second through electrode 140b may penetrate the second semiconductor layer 110b in the third direction DR3. At least a portion of the sidewall of the second through electrode 140b may be at least partially surrounded by the second semiconductor layer 110b. For example, at least a portion of the sidewall of the second through electrode 140b may be in contact with the second semiconductor layer 110b. Referring to FIG. 2, the second through electrode 140b may have a region protruded to a predetermined height along the third direction DR3 from the fourth surface 104. In this case, the protruded region, as shown in FIG. 2, may extend to the inside of the second upper wire structure 120b, which will be described later. In this case, the upper surface of the second through electrode 140b may be positioned at a height that is higher than the fourth surface 104. However, the present inventive concept is not limited thereto. For example, the upper surface of the second through electrode 140b may have substantially the same height as the fourth surface 104. For example, the upper surface of the second through electrode 140b may be coplanar with the fourth surface 104.

The second through electrode 140b may be formed by drilling thousands of fine holes vertically penetrating the second semiconductor layer 110b, filling the holes with a conductive material, and connecting them as an electrode. At this time, holes penetrating the second semiconductor layer 110b may be formed by a deep etching. In an embodiment of the present inventive concept, holes penetrating the second semiconductor layer 110b may be formed by a laser. In an embodiment of the present inventive concept, the holes may be filled with a conductive material by an electrolytic plating. In an embodiment of the present inventive concept, the second through electrode 140b may include at least one of tungsten (W), aluminum (Al), copper (Cu), or alloys thereof.

The second connection pads 151b and 152b may be positioned on the upper surface of second through electrode 140b. For example, the second connection pads 151b and 152b may be positioned above the upper surface of the second through electrode 140b. The second connection pads 151b and 152b may be adjacent to the fourth surface 104 of the second semiconductor layer 110b. The second connection pads 151b and 152b may be commonly connected to the first through electrode 140a. The second connection pads 151b and 152b may be electrically connected to the upper surface of the second through electrode 140b. Referring to FIG. 2, a second upper wire structure 120b and an upper conductive pattern 130, which will be described later, may be positioned between the second connection pads 151b and 152b and the upper surface of the second through electrode 140b. The second connection pads 151b and 152b may be electrically connected to the second through electrode 140b through the wire patterns 121b and 122b and the upper conductive pattern 130 included in the second upper wire structure 120b. The upper surface of the second connection pads 151b and 152b may be in contact with the lower surface of the first connection pads 161a and 162a. In an embodiment of the present inventive concept, the interfaces where the first connection pads 161a and 162a and the second connection pads 151b and 152b respectively contact each other may be aligned on the same plane.

In an embodiment of the present inventive concept, the widths of the second connection pads 151b and 152b along the first direction DR1 may be substantially equal to each other. In an embodiment of the present inventive concept, the widths of the second connection pads 151b and 152b along the first direction DR1 may be substantially the same as the widths of the first connection pads 161a and 162a along the first direction DR1. However, the present inventive concept is not limited thereto, and for example, the widths of the second connection pads 151b and 152b along the first direction DR1 may be smaller or larger than the widths of the first connection pads 161a and 162a along the first direction DR1. The second connection pads 151b and 152b may have substantially the same thickness as each other. The upper surfaces of the second connection pads 151b and 152b may be positioned at substantially the same height as each other. For example, the upper surfaces of the second connection pads 151b and 152b may be substantially coplanar. The second connection pads 151b and 152b may have the lower surfaces positioned at substantially the same height as each other. For example, the lower surfaces of the second connection pads 151b and 152b may be substantially coplanar.

The second connection pads 151b and 152b may include a conductive material. For example, the second connection pads 151b and 152b may include at least one of a metal, a metal alloy, a conductive metal nitride, a conductive metal carbide, a conductive metal oxide, a conductive metal carbonitride, and/or two-dimensional material (2D material). The metal may include at least one of titanium (Ti), tantalum (Ta), tungsten (W), nickel (Ni), cobalt (Co), platinum (Pt), copper (Cu), and/or aluminum (Al). In an embodiment of the present inventive concept, each of the second connection pads 151b and 152b included in one second connection pad part 150b may include the same conductive material as each other. For example, the second connection pads 151b and 152b may include copper (Cu). However, the present inventive concept is not limited thereto. For example, the second connection pads 151b and 152b may include different types of conductive materials from each other.

The second connection pads 151b and 152b may have the upper surfaces in contact with the first connection pads 161a and 162a, respectively. Accordingly, the second connection pads 151b and 152b may provide the passage of an electrical signal flowing from the second semiconductor chip 100B to the first semiconductor chip 100A, or from the first semiconductor chip 100A to the second semiconductor chip 100B.

In an embodiment of the present inventive concept, the first semiconductor chip 100A may further include a first lower wire structure 170a and insulating layers 183 and 184 positioned on the first surface 101 of the first semiconductor layer 110a.

The first lower wire structure 170a may be positioned between the first surface 101 of the first semiconductor layer 110a and the first connection pads 161a and 162a. Referring to FIG. 2, the first lower wire structure 170a may include first lower wire patterns MPa, and a first lower wire insulation layer 173a at least partially surrounding the first lower wire patterns MPa. The first lower wire patterns MPa may be stacked on each other in the third direction DR3. Each first lower wire pattern MPa may include at least one first lower wire layer 171a and first lower wire via 172a.

Referring to FIG. 2, at least two or more first lower wire layers 171a may be spaced apart from each other in the third direction DR3 within the first lower wire insulation layer 173a. The first lower wire via 172a may be positioned between two first lower wire layers 171a that are positioned in different layers from each other. The first lower wire via 172a may have the upper surface in contact with the lower surface of any one of the two first lower wire layers 171a that are positioned in different layers. The first lower wire via 172a may have the lower surface in contact with the upper surface of any one of two first lower wire layers 171a that are positioned in different layers. The first lower wire via 172a may electrically connect two first lower wire layers 171a positioned in different layers.

The first lower wire via 172a may also be positioned between the first lower wire layer 171a and the first connection pads 161a and 162a. For example, the first lower wire via 172a may have the lower surface, which is in contact with the upper surface of the first connection pads 161a and 162a, and the upper surface, which is in contact with the lower surface of the first lower wire layer 171a. Each of the first lower wire vias 172a may have the lower surface, which is in contact with the upper surface of any one of the first connection pads 161a and 162a, and the upper surface, which is in contact with the lower surface of the first lower wire layer 171a.

In an embodiment of the present inventive concept, each of the first connection pads 161a and 162a may be in contact with at least one of the plurality of first lower wire patterns MPa. For example, referring to FIG. 2, among the first lower wire patterns MPa stacked in the third direction DR3, the first lower wire pattern MPa positioned at the bottom may be commonly connected with the first connection pads 161a and 162a. For example, the first lower wire pattern MPa positioned at the bottom may include a first lower wire layer 171a and at least two first lower wire vias 172a commonly connected to the first lower wire layer 171a. Each of the lowermost first lower wire vias 172a, which are included in the first lower wire pattern MPa, may be in contact with the upper surface of any one of the first connection pads 161a and 162a. For example, the first connection pads 161a and 162 may be in contact with a corresponding lowermost first lower wire via 172a. Among the first lower wire layers 171a, the uppermost first lower wire layer 171a may be directly connected to the first through electrode 140a. A portion of the upper surface of the uppermost first lower wire layer 171a may be in contact with the lower surface of the first through electrode 140a. According to the embodiment, the first connection pads 161a and 162a included in one first connection pad part 160a may be commonly connected to the first through electrode 140a. Unlike shown in FIG. 2, each of the first connection pads 161a and 162 may be in contact with the first lower wire pattern MPa other than the first lower wire pattern MPa positioned at the bottom among the plurality of first lower wire patterns MPa. For example, among two first connection pads 161a and 162a shown in FIG. 2, only one may be connected to the lowermost first lower wire pattern MPa, and the other may be in contact with another first lower wire pattern MPa. In addition, both of two first connection pads 161a and 162a shown in FIG. 2 may be in contact the first lower wire pattern MPa other than the lowermost first lower wire pattern MPa.

In an embodiment of the present inventive concept, the first lower wire layers 171a and the first lower wire vias 172a may include a conductive material. For example, the first lower wire layers 171a and the first lower wire vias 172a may respectively include at least one of a metal, a metal alloy, a conductive metal nitride, a conductive metal carbide, a conductive metal oxide, a conductive metal carbonitride, and/or two-dimensional material (2D material). The metal may include at least one of titanium (Ti), tantalum (Ta), tungsten (W), nickel (Ni), cobalt (Co), platinum (Pt), copper (Cu), and/or aluminum (Al).

The first lower wire insulation layer 173a may be disposed between the first lower wire layers 171a and the first lower wire vias 172a to insulate them. The first lower wire insulation layer 173a may surround the first lower wire layers 171a and the first lower wire vias 172a. The first lower wire layers 171a and the first lower wire vias 172a may be positioned within the first lower wire insulation layer 173a. The first lower wire insulation layer 173a, for example, may include, for example, at least one of silicon oxide (SiO₂), silicon nitride (SiN), silicon oxynitride (SiON), or low dielectric layers. The first lower wire layers 171a and the first lower wire vias 172a may include a metal (e.g., copper).

The third insulating layer 183 may be positioned on the lower surface of the first lower wire insulation layer 173a. For example, the third insulating layer 183 may have the upper surface in contact with the lower surface of the first lower wire insulation layer 173a. The third insulating layer 183 may cover some regions of the sides of the first lower wire vias 172a. For example, some regions of the third insulating layer 183 may be penetrated in the third direction DR3 by the first lower wire vias 172a. Some regions of the lower surface of the third insulating layer 183 may be in contact with some regions of the upper surface of the first connection pads 161a and 162a. The third insulating layer 183 may include an insulating material. The third insulating layer 183, for example, may include at least one of silicon oxide (SiOₓ), silicon nitride (SiNₓ), silicon oxynitride (SiON), and/or a low dielectric constant material. The third insulating layer 183 may include a different material than the first lower wire insulation layer 173a. For example, the first lower wire insulation layer 173a includes silicon oxide (SiOₓ), the third insulating layer 183 may include silicon nitride (SiNₓ). The third insulating layer 183 may include the same material as that of the first lower wire insulation layer 173a. In this case, the boundary between the third insulating layer 183 and the first lower wire insulation layer 173a might not be recognized.

The fourth insulating layer 184 may be positioned on the lower surface of the third insulating layer 183. The upper surface of the fourth insulating layer 184 may be in contact with some regions of the lower surface of the third insulating layer 183. The lower surface of the fourth insulating layer 184 may be in contact with the upper surface of the second insulating layer 182, which will be described later. For example, the fourth insulating layer 184 may form the bonding with the second insulating layer 182, which will be described later. In an embodiment of the present inventive concept, the interface between the fourth insulating layer 184 and the second insulating layer 182 may be on the same plane as the interface between the first connection pads 161a and 162a and the second connection pads 151b and 152b. The fourth insulating layer 184 may at least partially surround the sides of the first connection pads 161a and 162a. The fourth insulating layer 184, for example, may include at least one of silicon oxide (SiOₓ), silicon nitride (SiNₓ), silicon oxynitride (SiON), and a low dielectric constant material. The fourth insulating layer 184 may include a different material from that of the third insulating layer 183. For example, when the third insulating layer 183 includes silicon nitride (SiNₓ), the fourth insulating layer 184 may include silicon oxide (SiOₓ). The fourth insulating layer 184 may include the same material as the third insulating layer 183. In this case, the boundary between the fourth insulating layer 184 and the third insulating layer 183 might not be recognized. In an embodiment of the present inventive concept, the fourth insulating layer 184 may include the same insulating material as that of the second insulating layer 182, which will be described later. In an embodiment of the present inventive concept, the fourth insulating layer 184 may include tetra-ethylene ortho silicate (TEOS).

In an embodiment of the present inventive concept, the second semiconductor chip 100B may further include a second upper wire structure 120b, an upper conductive pattern 130, and insulating layers 181 and 182 positioned on the fourth surface 104 of the second semiconductor layer 110b.

The second upper wire structure 120b may be positioned between the fourth surface 104 of the second semiconductor layer 110b and the second connection pads 151b and 152b. Referring to FIG. 2, the second upper wire structure 120b may include second upper wire layers 122b, second upper wire vias 121b, and a second upper wire insulation layer 123b at least partially surrounding the second upper wire layers 122b and the second upper wire vias 121b.

Referring to FIG. 2, at least two or more second upper wire layers 122b may be positioned to be spaced apart from each other in the third direction DR3 while inside the second upper wire insulation layer 123b. The second upper wire via 121b may be positioned between two second upper wire layers 122b that are positioned in different layers from each other. The second upper wire via 121b may have the upper surface in contact with the lower surface of any one of two second upper wire layers 122b that are positioned in different layers from each other. The second upper wire via 121b may have the lower surface in contact with the upper surface of any one of two second upper wire layers 122b that are positioned in different layers from each other. The second upper wire via 121b may electrically connect two second upper wire layers 122b, which are positioned in different layers from each other, to each other. Among the second upper wire vias 121b, the upper surface of the uppermost second upper wire via 121b positioned may be in contact with the lower surface of the upper conductive pattern 130. The second through electrode 140b and the upper conductive pattern 130 may be electrically connected to each other by the second upper wire vias 121b and the second upper wire layers 122b.

In an embodiment of the present inventive concept, the second upper wire layers 122b and the second upper wire vias 121b may include a conductive material. For example, the second upper wire layers 122b and the second upper wire vias 121b may include at least one of a metal, a metal alloy, a conductive metal nitride, a conductive metal carbide, a conductive metal oxide, a conductive metal carbonitride, and/or two-dimensional material (2D material), respectively. The metal may include at least one of titanium (Ti), tantalum (Ta), tungsten (W), nickel (Ni), cobalt (Co), platinum (Pt), copper (Cu), and/or aluminum (Al).

The second upper wire insulation layer 123b may be disposed between the second upper wire layers 122b and the second upper wire vias 121b to insulate them. The second upper wire insulation layer 123b may at least partially surround the second upper wire layers 122b and the second upper wire vias 121b. The second upper wire layers 122b and the second upper wire vias 121b may be positioned within the second upper wire insulation layer 123b. The second upper wire insulation layer 123b may include an insulating material. For example, the second upper wire insulation layer 123b may include at least one of silicon oxide (SiO2), silicon nitride (SiN), silicon oxynitride (SiON), and/or dielectric layers. In an embodiment of the present inventive concept, the second upper wire insulation layer 123b may include an oxide layer formed using high density plasma (HDP).

The upper conductive pattern 130 may be positioned on the second upper wire structure 120b. The upper conductive pattern 130 may be in contact with the upper surface of the second upper wire structure 120b. The upper conductive pattern 130 may have the lower surface in contact with the upper surface of the second upper wire vias 121b and the upper surface of the second upper wire insulation layer 123b. The upper conductive pattern 130 may be commonly connected to the plurality of second connection pads 151b and 152b. The upper surface of the upper conductive pattern 130 may be in contact with the lower surface of the second connection pads 151b and 152b.

The upper conductive pattern 130 may have a plate-like shape with a flat upper surface. For example, the upper conductive pattern 130 may have a polygonal shape. For example, the upper conductive pattern 130 may have a trapezoidal shape when viewed in cross-section. In other words, the width of the upper conductive pattern 130 along the first direction DR1 may gradually increase as it approaches the upper surface of the second upper wire structure 120b. However, the present inventive concept is not limited thereto, and for example, the width of the upper conductive pattern 130 along the first direction DR1 may be constant regardless of the distance from the upper surface of the second upper wire structure 120b. In an embodiment of the present inventive concept, the thickness of the upper conductive pattern 130 may be thick compared to the thickness of the second upper wire vias 121b and the second upper wire layers 122b. For example, the thickness of the upper conductive pattern 130 may be greater than the thickness of the second upper wire vias 121b and the second upper wire layers 122b. By making the thickness of the upper conductive pattern 130 sufficiently thick, the upper surface of the upper conductive pattern 130 that is in contact with the lower surface of the two pads 151b and 152b may be formed to be flat.

The upper conductive pattern 130 may include a conductive material. For example, the upper conductive pattern 130 may include at least one of a metal, a metal alloy, a conductive metal nitride, a conductive metal carbide, a conductive metal oxide, a conductive metal carbonitride, and/or two-dimensional material (2D material), respectively. The metal may include at least one of titanium (Ti), tantalum (Ta), tungsten (W), nickel (Ni), cobalt (Co), platinum (Pt), copper (Cu), and/or aluminum (Al).

The first insulating layer 181 may be positioned on the upper surface of the second upper wire structure 120b. The first insulating layer 181 may cover at least some regions and the sides of the upper surface of the upper conductive pattern 130. Some regions of the first insulating layer 181 may be penetrated in the third direction DR3 by the second connection pads 151b and 152b that are in contact with the upper surface of the upper conductive pattern 130. The first insulating layer 181 may at least partially surround some regions on the sides of the second connection pads 151b and 152b. The first insulating layer 181 may include an insulating material. In an embodiment of the present inventive concept, the first insulating layer 181 may include the same insulating material as that of the second upper wire insulation layer 123b. In this case, the boundary between the first insulating layer 181 and the second upper wire insulation layer 123b might not be recognized. However, the present inventive concept is not limited thereto, and for example, the first insulating layer 181 may include an insulating material that is different from that of the second upper wire insulation layer 123b. The first insulating layer 181 may include, for example, at least one of silicon oxide (SiO2), silicon nitride (SiN), silicon oxynitride (SiON), or dielectric layers. In an embodiment of the present inventive concept, the second upper wire insulation layer 123b may include an oxide layer formed using high density plasma (HDP).

The second insulating layer 182 may be positioned above the second upper wire structure 120b and the first insulating layer 181. The second insulating layer 182 may cover at least a partial region of the upper surface of the second upper wire structure 120b. The second insulating layer 182 may cover at least some regions and sides of the upper surface of the first insulating layer 181. Some regions of the second insulating layer 182 may be penetrated in the third direction DR3 by the second connection pads 151b and 152b that are in contact with the upper surface of the upper conductive pattern 130. The second insulating layer 182 may at least partially surround some regions on the sides of the second connection pads 151b and 152b. The upper surface of the second insulating layer 182 may be in contact with the lower surface of the fourth insulating layer 184. For example, the second insulating layer 182 may form the bonding with the fourth insulating layer 184. In an embodiment of the present inventive concept, the interface between the second insulating layer 182 and the fourth insulating layer 184 may be on the same plane as the interface between the first connection pads 161a and 162a and the second connection pads 151b and 152b.

The second insulating layer 182 may include an insulating material. In an embodiment, the second insulating layer 182 may include the same insulating material as the fourth insulating layer 184. In this case, the boundary between the second insulating layer 182 and the fourth insulating layer 184 might not be recognized. The second insulating layer 182 may include, for example, at least one of silicon oxide (SiO2), silicon nitride (SiN), silicon oxynitride (SiON), or dielectric layers. In an embodiment of the present, the second insulating layer 182 may include tetra-ethylene ortho silicate (TEOS).

The semiconductor package according to the embodiment may further include at least one or more insulating layers formed at the bonding area of the first semiconductor chip 100A and the second semiconductor chip 100B. For example, one or more insulating layers including silicon oxide (SiO2) or silicon nitride (SiN) may be further formed on the second insulating layer 182. The insulating layers positioned above the second insulating layer 182 may have a thinner thickness compared to the second insulating layer 182 or the fourth insulating layer 184.

Referring to FIG. 2, the first through electrode 140a of the first semiconductor chip 100A and the second through electrode 140b of the second semiconductor chip 100B can be electrically connected to each other by two pad bonding parts BR1 and BR2. In each of the pad bonding parts BR1 and BR2, the first connection pads 161a and 162a of the first semiconductor chip 100A and the second connection pads 151b and 152b of the second semiconductor chip 100B may be bonded to each other. In this case, even if an interconnection failure occurs in any one of the first pad bonding part BR1 or the second pad bonding part BR2, the first through electrode 140a and the second through electrode 140b are electrically connected to each other through the other pad bonding part.

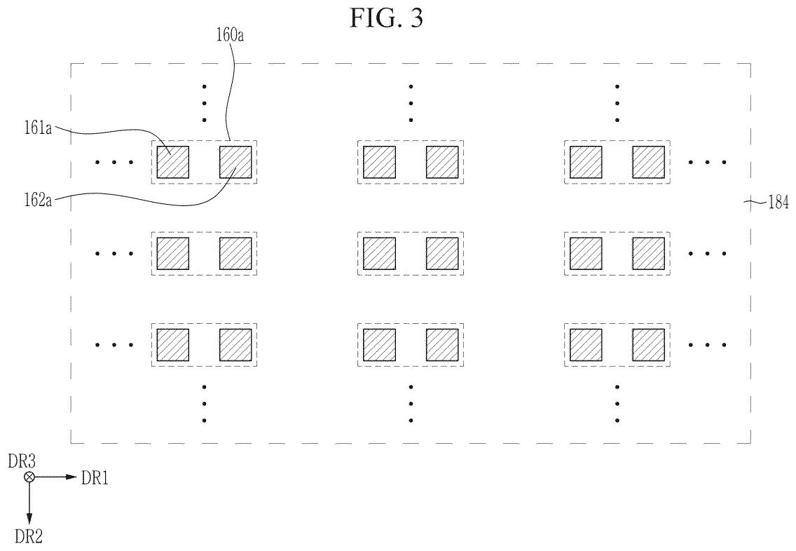

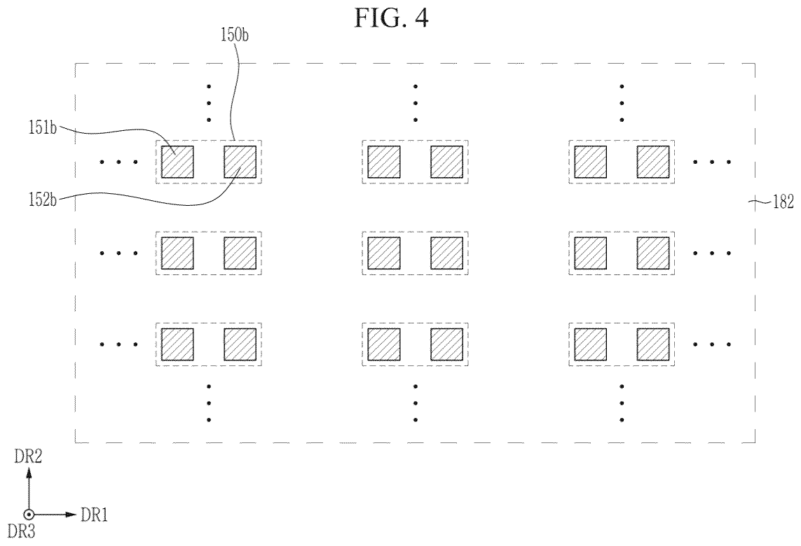

FIG. 3 and FIG. 4 are enlarged top plan views of a bonding part of a semiconductor package according to an embodiment of the present inventive concept. Specifically, FIG. 3 is the top plan view of a part of the lower surface of the first semiconductor chip 100A included in the region B of FIG. 1, viewed from the lower surface of the bottom of the first semiconductor chip 100A in the upward direction (the third direction DR3). FIG. 4 is the top plan view of a part of the upper surface of the second semiconductor chip 100B included in the region B of FIG. 1, viewed from the top of the upper surface of the second semiconductor chip 100B in the downward direction (the opposite direction of the third direction DR3).

Referring to FIG. 3, the plurality of first connection pad parts 160a included in the first semiconductor chip 100A may be arranged along the first direction DR1 and the second direction DR2 that intersects the first direction DR1. Each of the first connection pad parts 160a may include a plurality of first connection pads 161a and 162a. In FIG. 3, the first connection pad parts 160a are shown as including the plurality of first connection pads 161a and 162a, but the number of the first connection pads 161a and 162a included in one first connection pad part 160a is not limited thereto. Within the first connection pad part 160a, the plurality of first connection pads 161a and 162a may be arranged along the first direction DR1. In an embodiment of the present inventive concept, the interval between the plurality of first connection pad parts 160a arranged along the first direction DR1 may be larger than the interval between the plurality of first connection pad parts 160a arranged along the second direction DR2.

Referring to FIG. 4, the plurality of second connection pad parts 150b included in the second semiconductor chip 100B may be arranged along the first direction DR1 and the second direction DR2 that intersects the first direction DR1. Each second connection pad part 150b may include a plurality of second connection pads 151b and 152b. In FIG. 4, the second connection pad parts 150b are shown as including a plurality of second connection pads 151b and 152b, but the number of the second connection pads 151b and 152b included in one second connection pad part 150b is not limited thereto. Within second connection pad part 150b, the plurality of second connection pads 151b and 152b may be arranged along the first direction DR1. In an embodiment of the present inventive concept, the interval between the plurality of second connection pad parts 150b arranged along the first direction DR1 may be larger than the interval between the plurality of second connection pad parts 150b arranged along the second direction DR2.

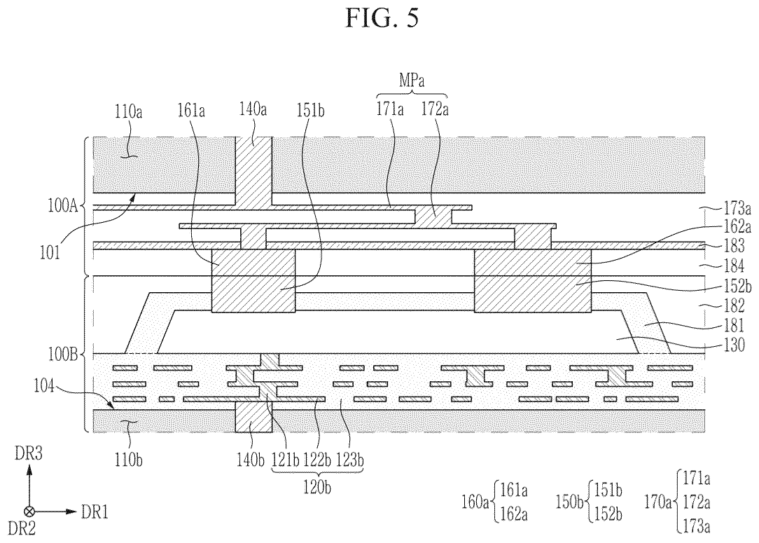

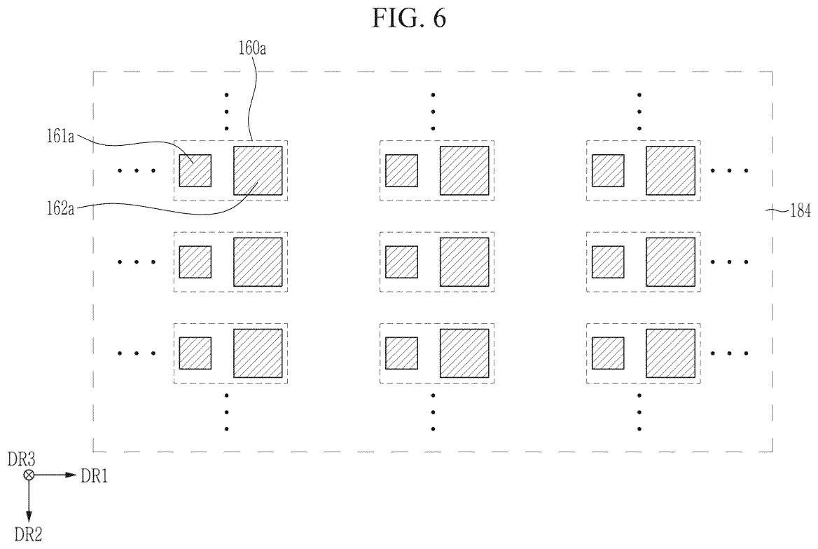

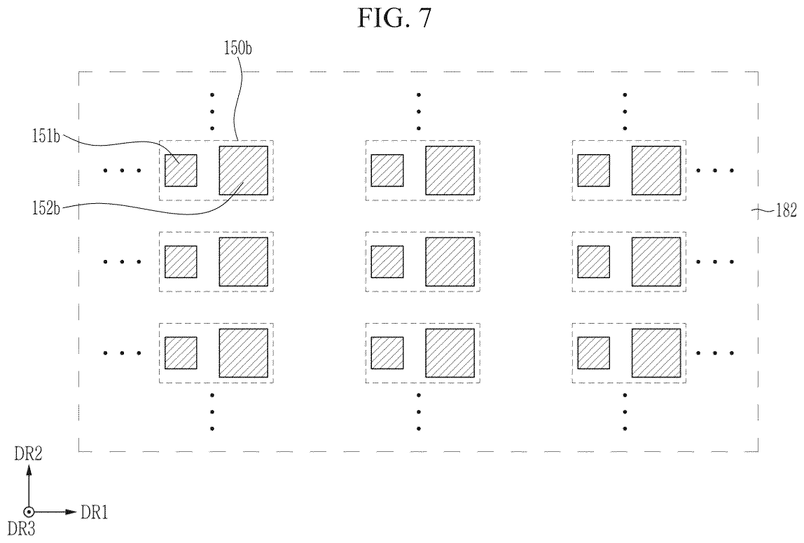

FIG. 5 to FIG. 7 are views to explain a semiconductor package according to an embodiment of the present inventive concept. Specifically, FIG. 5 is an enlarged cross-sectional view of a bonding part of a semiconductor package according to an embodiment of the present inventive concept. FIG. 6 and FIG. 7 are enlarged top plan views of the bonding part of the semiconductor package according to an embodiment of the present inventive concept. FIG. 6 is the top plan view of a part of the bottom surface of the first semiconductor chip 100A included in the region B of FIG. 1, viewed from the bottom of the lower surface of the first semiconductor chip 100A, in the upward direction (the third direction DR3). FIG. 7 is the top plan view of a portion of the upper surface of the second semiconductor chip 100B included in the region B of FIG. 1, viewed from the top of the upper surface of the second semiconductor chip 100B in the downward direction (opposite direction of the third direction DR3).

Since the semiconductor package shown in FIG. 5 to FIG. 7 is largely the same as the semiconductor package described above, the description thereof will be omitted or briefly discussed, and the differences will be mainly explained below. The semiconductor package according to the embodiment may be slightly different compared to the previous embodiments in that the size between the first connection pads 161a and 162a and the size between the second connection pads 151b and 152b are different.

Referring to FIG. 5 and FIG. 6, in the case of the semiconductor package according to the embodiment, the first connection pad 161a and 162a included in one first connection pad part 160a may have the different widths from each other. For example, if one first connection pad part 160a includes two first connection pads 161a and 162a, the width of one (e.g., 161a in FIG. 2) of two first connection pads 161a and 162a may be smaller than the width of the other first connection pad (e.g., 162a in FIG. 2).

Referring to FIG. 5 and FIG. 7, in the case of the semiconductor package according to the embodiment, the second connection pads 151b and 152b included in one second connection pad part 150b may have the different widths from each other. For example, if one second connection pad part 150b includes two second connection pads 151b and 152b, the width of any one (e.g., 151b in FIG. 2) of the two second connection pads 151b and 152b may be smaller than the width of another second connection pad (e.g., 152b in FIG. 2).

In the embodiment of the present inventive concept, each of the first connection pads 161a and 162a may have the same width as a corresponding second connection pad of the second connection pads 151b and 152b to which it is in contact with. For example, In FIG. 5, the first connection pad 161a positioned on the left may have the same width as the second connection pad 151b positioned on the left, and the first connection pad 162a positioned on the right may have the same width as the second connection pad 152b positioned on the right.

A dishing formed on the surface of the pads in the CMP process may be removed as the pads expand in the subsequent heat treatment process, and thus, the entire bonding area of two pads may be in contact with each other. The degree to which the pads expand may depend on the heat treatment condition and the size of the pads. Therefore, it may be important to perform the heat treatment (the annealing) process on the semiconductor package under appropriate temperatures and time conditions so that the entire area of two pads to be bonded is in complete contact with each other.

Referring to FIG. 5. two connection pads 161a and 151b positioned on the left may have the smaller width compared to two connection pads 162a and 152b positioned on the right. At this time, under the same heat treatment condition, the degree of the expansion of the small-width connection pads 161a and 151b and the large-width connection pads 162a and 152b may be different from each other. For example, the degree of the expansion of the connection pads 162a and 152b with the large widths may be greater than that of the connection pads 161a and 151b with the small widths under the same heat treatment condition. In this case, even if a connection failure occurs in one of the bonding between two small-width connection pads 161a and 151b and the bonding between two large-width connection pads 162a and 152b, the first semiconductor chip 100A and the second semiconductor chip 100B may be bonded to each other by the other bonding. For example, if the heat treatment time is excessively long or the heat treatment temperature is excessively high, the connection failure may occur between two large-width connection pads 161a and 151b. In this case, the first semiconductor chip 100A and the second semiconductor chip 100B may be electrically connected by the bonding between two narrow-width connection pads 162a and 152b.

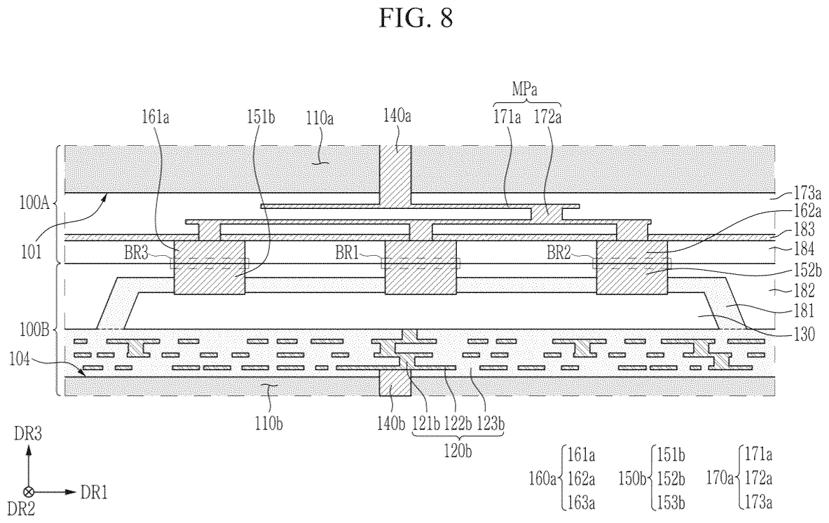

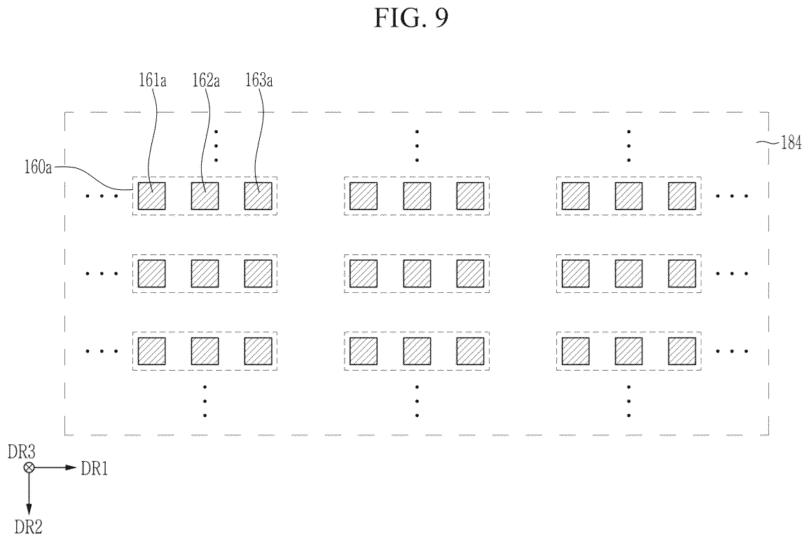

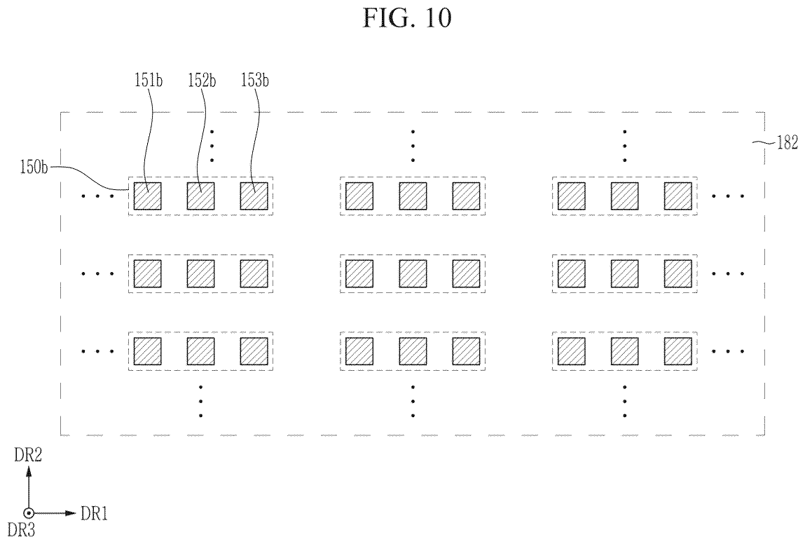

FIG. 8 to FIG. 10 are views to explain a semiconductor package according to an embodiment of the present inventive concept. In detail, FIG. 8 is an enlarged cross-sectional view of a bonding part of a semiconductor package according to an embodiment of the present inventive concept. FIG. 9 and FIG. 10 are enlarged top plan views of a bonding part of a semiconductor package according to an embodiment of the present inventive concept. FIG. 9 is the top plan view of a part of the lower surface of the first semiconductor chip 100A included in the region B of FIG. 1, viewed from the bottom of the lower surface of the first semiconductor chip 100A, in the upward direction (the third direction DR3). FIG. 10 is the top plan view of a portion of the upper surface of the second semiconductor chip 100B included in the region B of FIG. 1, viewed from the top of the upper surface of the second semiconductor chip 100B in the downward direction (the opposite direction of the third direction DR3).

Since the semiconductor package shown in FIG. 8 to FIG. 10 is largely the same as the semiconductor package described above, the description thereof will be omitted or briefly discussed, and the differences will be mainly explained below. In the semiconductor package according to the embodiment, the number of the connection pads may be slightly different compared to the previous embodiments.

Referring to FIG. 8 to FIG. 10, a first semiconductor chip 100A according to an embodiment of the present inventive concept may include three first connection pads 161a, 162a, and 163a. Three first connection pads 161a, 162a, and 163a may be commonly connected to the first lower wire layer 171a, which is positioned at the bottom of the first lower wire layers 171a.

Referring to FIG. 8 to FIG. 10, the second semiconductor chip 100B according to the embodiment may include three second connection pads 151b, 152b, and 153b. Three second connection pads 151b, 152b, and 153b may be commonly connected to the upper conductive pattern 130.

According to the embodiment of the present inventive concept, the first through electrode 140a of the first semiconductor chip 100A and the second through electrode 140b of the second semiconductor chip 100B may be electrically connected to each other by three pad bonding parts BR1, BR2, and BR3. In this case, even if an interconnection failure occurs in any one of the first pad bonding part BR1, the second pad bonding part BR2, and the third pad bonding part BR3, or two pad bonding parts, the first through electrode 140a and the second through electrode 140b may be electrically connected to each other through the remaining bonding parts. Therefore, the reliability may be increased in the hybrid bonding process of the semiconductor package according to the embodiment.

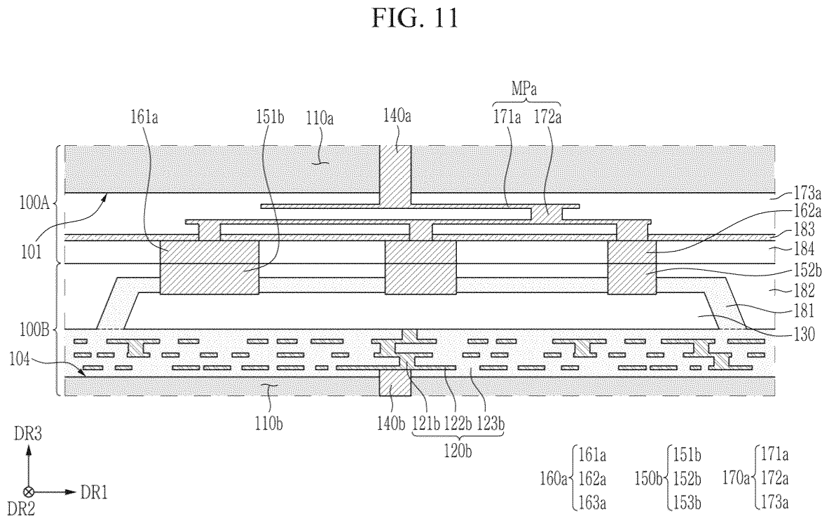

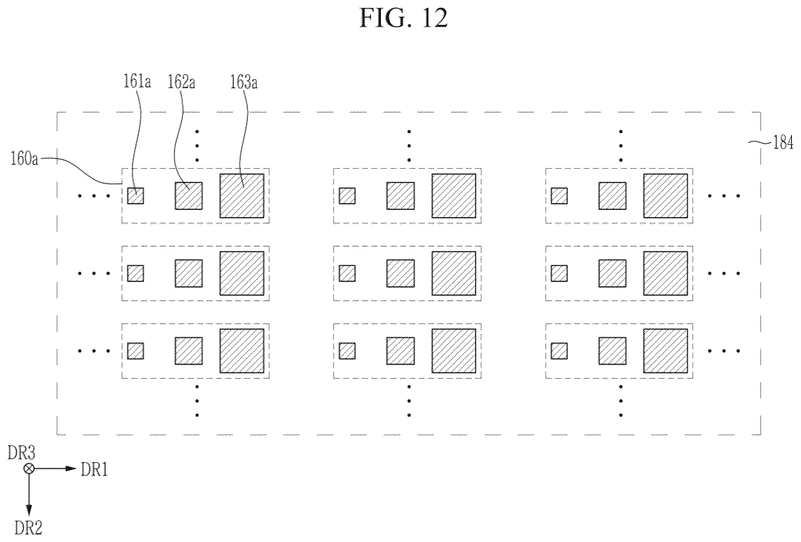

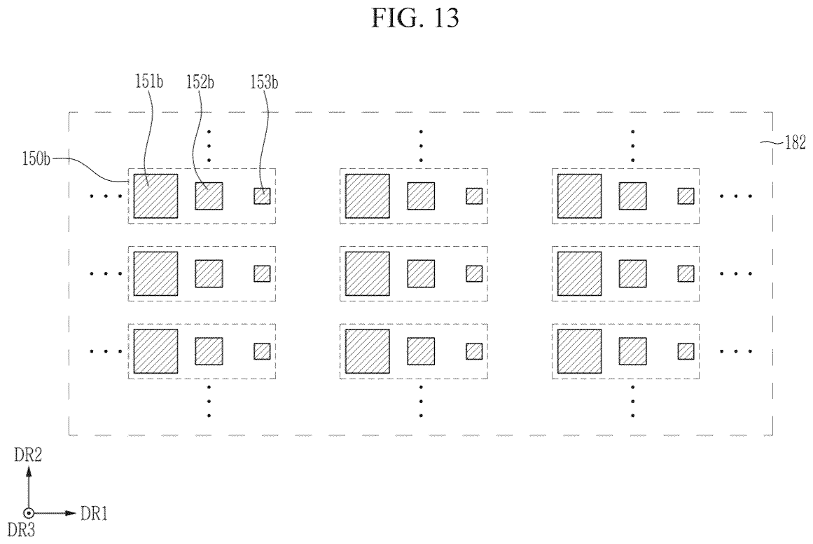

FIG. 11 to FIG. 13 are views to explain a semiconductor package according to an embodiment of the present inventive concept. Specifically, FIG. 11 is an enlarged cross-sectional view of a bonding part of a semiconductor package according to an embodiment of the present inventive concept. FIG. 12 and FIG. 13 are enlarged top plan views of a bonding part of a semiconductor package according to an embodiment of the present inventive concept. FIG. 12 is the top plan view of a part of the lower surface of the first semiconductor chip 100A included in the region B of FIG. 1, viewed from the bottom of the lower surface of the first semiconductor chip 100A, in the upward direction (the third direction DR3). FIG. 13 is the top plan view of a portion of the upper surface of the second semiconductor chip 100B included in the region B of FIG. 1, viewed from the top of the upper surface of the second semiconductor chip 100B in the downward direction (the opposite direction of the third direction DR3).

Since the semiconductor package shown in FIG. 11 to FIG. 13 is largely the same as the semiconductor package described above, the description thereof will be omitted or briefly discussed, and the differences will be mainly explained below. The semiconductor package according to the embodiment may have some differences in the number of the connection pads and the size of the connection pads compared to the previous embodiments.

Referring to FIG. 11 to FIG. 13, the first semiconductor chip 100A according to the embodiment may include first connection pads 161a, 162a, and 163a having three different sizes from each other. The second semiconductor chip 100B according to the embodiment may include second connection pads 151b, 152b, and 153b having three different sizes from each other. In FIG. 11 to FIG. 13, the first connection pads 161a, 162a, and 163a and the second connection pads 151b, 152b, and 153b are shown to gradually increase in the width as they move toward the first direction DR1, but the positions of each of the connection pads having the different sizes are not limited to the present embodiment. For example, in the embodiment, the first connection pads 161a, 162a, and 163a and the second connection pads 151b, 152b, and 153b may gradually increase in the width as they move toward the opposite direction of the first direction. In addition, in an embodiment of the present inventive concept, in the first connection pads 161a, 162a, and 163a and the second connection pads 151b, 152b, and 153b, among three connection pads, the connection pads 162a and 152b positioned in the middle may have the largest width.

In an embodiment of the present inventive concept, the first connection pads 161a, 162a, and 163a may be in contact with the second connection pads 151b, 152b, and 153b, respectively, and the connection pads that are in contact with each other may have substantially the same width. For example, in FIG. 11, the first connection pad 161a positioned on the leftmost side has substantially the same width as the second connection pad 151b positioned on the leftmost side. Further, the first connection pad 162a positioned in the center has substantially the same width as the second connection pad 152b positioned in the center, and the first connection pad 163a positioned on the rightmost side may have substantially the same width as the second connection pad 153b positioned on the rightmost side. As the semiconductor package according to the embodiment includes the connection pads having various sizes, the reliability in the bonding process of the semiconductor package may be increased.

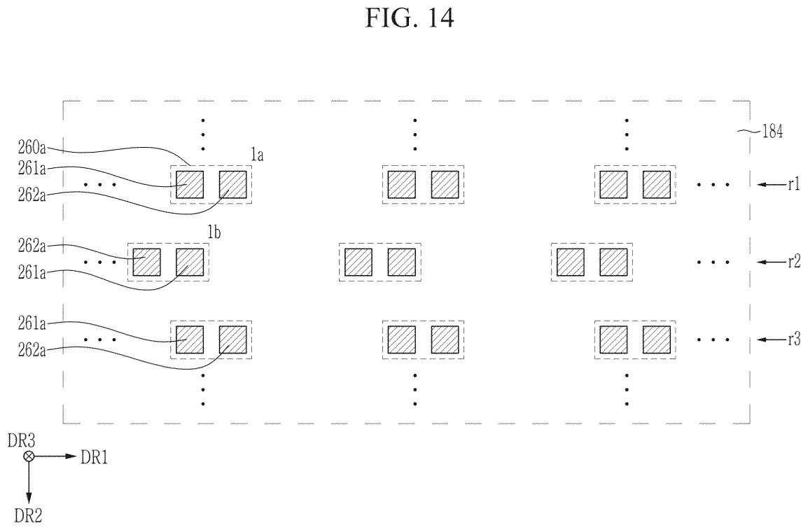

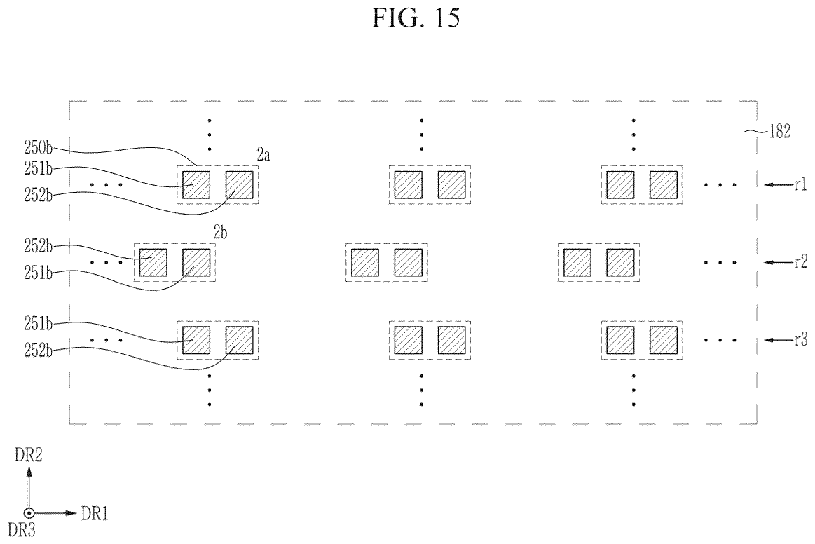

FIG. 14 and FIG. 15 are views to explain a semiconductor package according to an embodiment of the present inventive concept. In detail, FIG. 14 and FIG. 15 are enlarged top plan views of a bonding part of a semiconductor package according to an embodiment of the present inventive concept. FIG. 14 is the top plan view of a part of the lower surface of the first semiconductor chip 100A included in the region B of FIG. 1, viewed from the bottom of the lower surface of the first semiconductor chip 100A, in the upward direction (the third direction DR3). FIG. 15 is the top plan view of a portion of the upper surface of the second semiconductor chip 100B included in the region B of FIG. 1, viewed from the top of the upper surface of the second semiconductor chip 100B in the downward direction (the opposite direction of the third direction DR3).

Since the semiconductor package shown in FIG. 14 and FIG. 15 is largely the same as the semiconductor package described above, the description thereof will be omitted or briefly discussed, and the differences will be mainly explained below. In the semiconductor package according to the embodiment, the position of the connection pads on a plane may be slightly different compared to the previous embodiments.

Referring to FIG. 14, the plurality of first connection pad parts 260a included in the first semiconductor chip 100A may have zigzag or alternating arrangement along the second direction DR2. In the embodiment, the first connection pad parts 260a may include first main connection pads 261a and first sub-connection pads 262a, respectively. In the embodiment, the first main connection pads 261a may be arranged side by side along the second direction DR2. In the embodiment, the first sub-connection pads 262a may be alternately arranged on one side and the other side of each of the first main connection pads 261a.

In an embodiment, the first semiconductor chip 100A may include a plurality of pad rows r1, r2, and r3 spaced apart in the second direction DR2. Each of the plurality of pad rows r1, r2, and r3 may include a plurality of first connection pad parts 260a arranged in the first direction DR1. In the embodiment, any one of two first connection pads 261a and 262a included in one first connection pad part 260a may overlap any one of two first connection pads 261a and 262a included in another first connection pad part 260a adjacent in the second direction DR2. In the embodiment, among two first connection pads 261a and 262a included in one first connection pad part 260a, the other one might not overlap two first connection pads 261a and 262a included in another first connection pad part 260a adjacent to the second direction DR2.

In detail, referring to FIG. 14, the first connection pad part 1a included in the first pad row r1 and first connection pad part 1b included in the second pad row r2 may include one first main connection pad 261a and one first sub-connection pad 262a, respectively. At this time, the first main connection pad 261a included in the first connection pad part 1a may overlap the first main connection pad 261a included in the first connection pad part 1b in the second direction DR2. However, the first sub-connection pad 262a included in the first connection pad part 1a might not overlap both connection pads 261a and 262a included in the first connection pad part 1b in the second direction DR2.

Referring to FIG. 15, the plurality of second connection pad parts 250b included in the second semiconductor chip 100B may be arranged with a zigzag arrangement or an alternating arrangement along the second direction DR2. In an embodiment of the present inventive concept, the second connection pad parts 250b may include a second main connection pad 251b and a second sub-connection pad 252b, respectively. In the embodiment, the second main connection pads 251b may be arranged side by side along the second direction DR2. In the embodiment, the second sub-connection pads 252b may be alternately arranged on one side and the other side of each of the second main connection pads 251b.

In an embodiment of the present inventive concept, the second semiconductor chip 100B may include a plurality of pad rows r1, r2, and r3 that are spaced apart in the second direction DR2. Each of the plurality of pad rows r1, r2, and r3 may include a plurality of second connection pad parts 250b arranged in the first direction DR1. In an embodiment of the present inventive concept, any one of two second connection pads 251b and 252b included in one second connection pad part 250b may overlap any one of two second connection pads 251b and 252b included in another second connection pad part 250b adjacent to the second direction DR2 in the second direction DR2. In the embodiment, the other one of two second connection pads 251b and 252b included in one second connection pad part 250b might not overlap two second connection pads 251b and 252b included in the other second connection pad part 250b adjacent to the second direction DR2.

In detail, referring to FIG. 15, the second connection pad part 2a included in the first pad row r1 and the second connection pad part 2b included in the second pad row r2 may include one second main connection pad 251b and one second sub-connection pad 252b, respectively. At this time, the second main connection pad 251b included in the second connection pad part 2a may overlap the second main connection pad 251b included in the second connection pad part 2b in the second direction DR2. However, the second sub-connection pad 252b included in the second connection pad part 2a might not overlap both connection pads 251b and 252b included in the second connection pad part 2b in the second direction DR2.

According to the embodiment, an interference between electrical signals provided to the sub-connection pads 262a or 252b included in the different pad rows may be minimized.

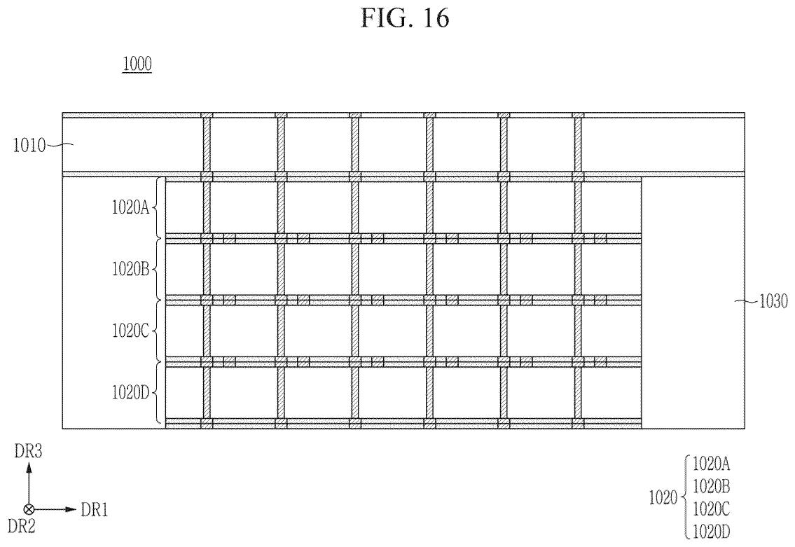

FIG. 16 is a view showing a semiconductor package according to an embodiment of the present inventive concept.

Referring to FIG. 16, the semiconductor package 1000 may include a semiconductor chip stacking structure 1020, a top die 1010, and a molding material 1030.

The semiconductor chip stacking structure 1020 may have a structure in which a plurality of semiconductor chips 1020A to 1020D are stacked in one direction (e.g., the third direction DR3). The top die 1010 may be placed on the semiconductor chip stacking structure 1020. In an embodiment of the present inventive concept, the top die 1010 may have a larger width along the first direction DR1 compared to the semiconductor chip stacking structure 1020.

Each of the plurality of semiconductor chips 1020A to 1020D stacked in the semiconductor chip stacking structure 1020 may be a memory chip. The top die 1010 may be a buffer die or a logic die. For example, the top die 1010 may be a central processing unit (CPU) chip, a graphic processing unit (GPU) chip, or an application processor (AP) chip.

The semiconductor chip stacking structure 1020 and the top die 1010 may be bonded to each other by a hybrid bonding. The semiconductor chips 1020A to 1020D included in the semiconductor chip stacking structure 1020 may be respectively bonded to each other by a hybrid bonding. The hybrid bonding may be performed through the bonding part included in each semiconductor chip 1020A to 1020D, or the top die 1010. The bonding part may be a part where each semiconductor chip is in contact with each other when the plurality of semiconductor chips 100A to 100D are stacked and connected to each other. In addition, when one of the plurality of semiconductor chips 1020A to 1020D and the top die 1010 are connected to each other, the bonding part may be a part where the semiconductor chip and the top die 1010 are in contact with each other. For the hybrid bonding, the contents of the hybrid bonding described with reference to FIG. 1 to FIG. 8 may be equally applied.

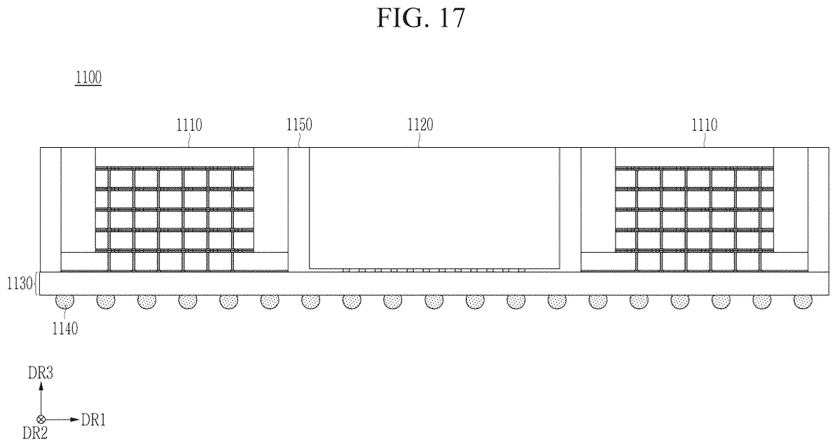

FIG. 17 is a cross-sectional view showing a 2.5D semiconductor package including a bonding structure according to an embodiment of the present inventive concept.

A semiconductor package 1100 of FIG. 17 may include a plurality of first semiconductor chips 1110 and a second semiconductor chip 1120, an interposer 1130, and a molding material 1150. The first semiconductor chip 1110 may include the semiconductor stacking structure, the bottom die, and the molding material described with reference to FIG. 1. The second semiconductor chip 1120 may be a logic die.

A substrate may be placed under the interposer 1130. Connection members may be placed on the lower surface of the interposer 1130. In an embodiment of the present inventive concept, the interposer 1130 may include a silicon interposer.

The first semiconductor chip 1110 and the second semiconductor chip 1120 may be placed on the interposer 1130. The first semiconductor chip 1110 and the second semiconductor chip 1120 may be bonded to the interposer 1130 by the hybrid bonding. The second semiconductor chip 1120 may include connection pads and insulating layers for hybrid bonding. For the hybrid bonding, the contents of the hybrid bonding described with reference to FIG. 1 to FIG. 18 may be equally applied.

The second semiconductor chip 1120 may be placed side-by-side with the first semiconductor chips 1110 between the first semiconductor chips 1110. In an embodiment of the present inventive concept, the second semiconductor chip 1120 may include a system on chip (SoC). In an embodiment of the present inventive concept, the second semiconductor chip 1120 may include a central processing unit (CPU) or a graphics processing unit (GPU).

The molding material 1150 may be placed on the interposer 1130 and mold the first semiconductor chip 1110 and the second semiconductor chip 1120. The molding material 1150 may serve to protect and insulate the first semiconductor chips 1110 and second semiconductor chips 1120. In one embodiment of the present inventive concept, the molding material 1150 may be formed of a thermosetting resin, such as epoxy resin. In an embodiment of the present inventive concept, the molding material 1150 may be an epoxy molding compound (EMC). In an embodiment of the present inventive concept, the molding process with the molding material 1150 may include a compression molding or transfer molding process.

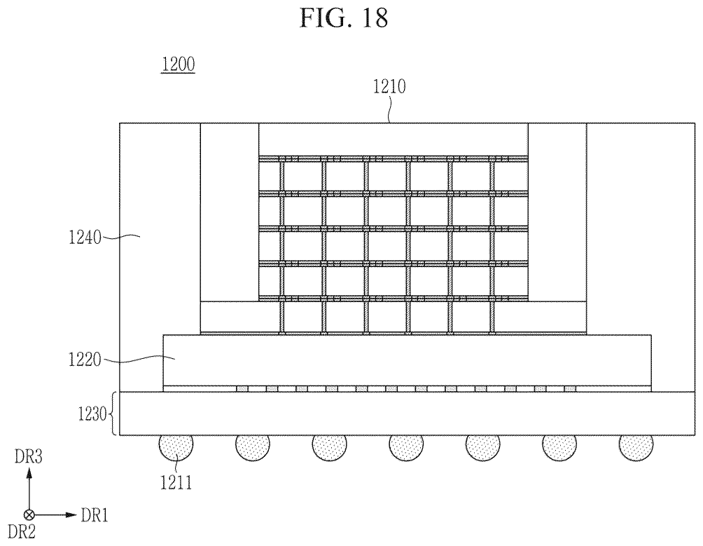

FIG. 18 is a cross-sectional view showing a 3D semiconductor package including a bonding structure according to an embodiment of the present inventive concept.

A semiconductor package 1200 of FIG. 18 may include a first semiconductor chip 1210 and a second semiconductor chip 1220, an interposer 1230, and a molding material 1240. The first semiconductor chip 1210 may include the semiconductor stacking structure, the bottom die, and the molding material described with reference to FIG. 1. The second semiconductor chip 1220 may be a logic die.

A substrate can be placed below the interposer 1230. Connection members may be placed on the lower surface of the interposer 1230. In an embodiment of the present inventive concept, the interposer 1230 may include a silicon interposer. The second semiconductor chip 1220 may be placed on the interposer 1230. The second semiconductor chip 1220 may be bonded to the interposer 1230 by hybrid bonding. For the hybrid bonding, the contents of the hybrid bonding described with reference to FIG. 1 to FIG. 18 may be applied in the same way.

In an embodiment of the present inventive concept, the second semiconductor chip 1220 may include a system on chip (SoC). In an embodiment of the present inventive concept, the second semiconductor chip 1220 may include a central processing unit (CPU) or a graphics processing unit (GPU).

The first semiconductor chip 1210 may be placed on the second semiconductor chip 1220. The first semiconductor chip 1210 may be bonded to the second semiconductor chip 1220 by hybrid bonding. For the hybrid bonding, the contents of the hybrid bonding described with reference to FIG. 1 to FIG. 18 may be applied in the same way.

The molding material 1240 may be placed on the interposer 1230 and mold the first semiconductor chip 1210 and the second semiconductor chip 1220. The molding material 1240 may serve to protect and insulate the first semiconductor chip 1210 and the second semiconductor chip 1220. In one embodiment of the present inventive concept, the molding material 1240 may be formed of a thermosetting resin, such as epoxy resin. In an embodiment of the present inventive concept, the molding material 1240 may be an epoxy molding compound (EMC). In an embodiment of the present inventive concept, the molding process with molding material 1240 may include a compression molding or a transfer molding process.

While the present inventive concept has been shown and described with reference to the embodiments thereof, it will be apparent to those of ordinary skill in the art that various changes in form and detail may be made thereto without departing from the spirit and scope of the present inventive concept.

What is claimed is:

1. A semiconductor package comprising:
a first semiconductor chip; and
a second semiconductor chip connected to the first semiconductor chip,
wherein the first semiconductor chip includes:
a first semiconductor layer;
a first through electrode penetrating the first semiconductor layer; and
a first connection pad part positioned on the first semiconductor layer and including a plurality of first connection pads connected to the first through electrode,
wherein the second semiconductor chip includes:
a second semiconductor layer;
a second through electrode penetrating the second semiconductor layer; and
a second connection pad part positioned on the second semiconductor layer to face the first connection pad part and including a plurality of second connection pads connected to the second through electrode,
wherein the plurality of first connection pads is in contact with the plurality of second connection pads, respectively.

2. The semiconductor package of claim 1, wherein:
the lower surface of at least one of the plurality of first connection pads is in contact with the upper surface of at least one of the plurality of second connection pads, and
the lower surface of another one of the plurality of first connection pads is in contact with the lower surface of another one of the plurality of second connection pads.

3. The semiconductor package of claim 1, wherein:
the plurality of first connection pad parts are arranged along a first direction and a second direction that intersects the first direction,
the interval between the plurality of first connection pad parts along the first direction is greater than the interval between the plurality of first connection pad parts along the second direction, and
the plurality of first connection pads are arranged along the first direction within the first connection pad part.

4. The semiconductor package of claim 1, wherein:
the plurality of second connection pad parts are arranged along a first direction and a second direction that intersects the first direction,
the interval between the plurality of second connection pad parts along the first direction is greater than the interval between the plurality of second connection pad parts along the second direction, and
the plurality of second connection pads are arranged along the first direction within the second connection pad part.

5. The semiconductor package of claim 1, wherein:
the first semiconductor chip further includes a first lower wire structure positioned between the first connection pad part and the first through electrode, and connecting between the first connection pads and the first through electrode.

6. The semiconductor package of claim 5, wherein:
the first lower wire structure includes a plurality of first lower wire patterns stacked on each other in a vertical direction, and
each of the plurality of first connection pads is in contact with at least one of the plurality of first lower wire patterns.

7. The semiconductor package of claim 6, wherein:
the plurality of first connection pads are in common contact with the first lower wire pattern that is located at a bottom among the plurality of first lower wire patterns,
the first lower wire pattern positioned at the bottom among the plurality of first lower wire patterns includes a first lower wire layer and first lower wire vias in common contact with the first lower wire layer, and
among the first lower wire vias, a first first lower wire via is in contact with one of the first connection pads, and among the first lower wire vias, a second first lower wire via is in contact with another one of the first connection pads.

8. The semiconductor package of claim 1, wherein:
the second semiconductor chip further includes an upper conductive pattern placed between the second connection pad part and the second through electrode, and
the upper conductive pattern is in contact with the plurality of second connection pads.

9. The semiconductor package of claim 1, wherein:
the first semiconductor chip includes two first connection pads of different widths, and
the second semiconductor chip includes two second connection pads of different widths.

10. The semiconductor package of claim 1, wherein:
the first semiconductor chip includes three first connection pads of different widths, and
the second semiconductor chip includes three second connection pads of different widths.

11. The semiconductor package of claim 1, wherein:
the plurality of first connection pad parts are arranged with a zigzag arrangement along the second direction,
each of the plurality of first connection pad parts includes a first main connection pad and a first sub-connection pad,
the first main connection pad of the plurality of first connection pad parts is arranged side by side along the second direction, and
the second sub-connection pad of the plurality of first connection pad parts is alternately arranged on one side and the other side of the first main connection pad.

12. The semiconductor package of claim 1, wherein:
the interfaces where the first connection pads and the second connection pads respectively contact each other are aligned on a same plane.

13. The semiconductor package of claim 1, further comprising:
a first insulating layer surrounding the sides of the first connection pads,
a second insulating layer surrounding the sides of the second connection pads, and having an upper surface in contact with the lower surface of the first insulating layer, and
the interface between the first insulating layer and the second insulating layer is on the same plane as the interface of the first connection pad and the second connection pad.

14. The semiconductor package of claim 1, wherein:
the first connection pad and the second connection pad include copper (Cu).

15. A semiconductor package comprising:
a first semiconductor chip; and
a second semiconductor chip connected to the first semiconductor chip,
wherein the first semiconductor chip includes:
a first semiconductor layer;
a first through electrode penetrating the first semiconductor layer in a thickness direction;
a first connection pad part positioned on one surface of the first semiconductor layer and including a plurality of first connection pads connected to the first through electrode;
a lower wire structure positioned between the first connection pad part and the first through electrode, and connecting the first connection pads to the first through electrode; and
a first insulating layer at least partially surrounding the first connection pads,
wherein the second semiconductor chip includes:
a second semiconductor layer;
a second through electrode penetrating the second semiconductor layer;
a second connection pad part positioned on one surface of the second semiconductor layer to face the first connection pad part and including a plurality of second connection pads connected to the second through electrode;
an upper wire structure positioned on the second through electrode;
an upper conductive pattern positioned on the upper wire structure and having an upper surface in contact with the plurality of second connection pads; and
a second insulating layer at least partially surrounding the second connection pads and having an upper surface in contact with the lower surface of the first insulating layer,
wherein the plurality of first connection pads is in contact with the plurality of second connection pads, respectively, and
the interface of the first insulating layer and the second insulating layer is on the same plane as the interface of the first connection pad and the second connection pad.

16. The semiconductor package of claim 15, wherein:
the lower surface of at least one of the plurality of first connection pads is in contact with the upper surface of at least one of the plurality of second connection pads, and
the lower surface of another one of the plurality of first connection pads is in contact with the lower surface of another one of the plurality of second connection pads.

17. The semiconductor package of claim 15, wherein:
the first semiconductor chip includes two first connection pads of different widths,
the second semiconductor chip includes two second connection pads of different widths.

18. The semiconductor package of claim 15, wherein:
the first semiconductor chip includes three first connection pads of different widths, and
the second semiconductor chip includes three second connection pads of different widths.

19. The semiconductor package of claim 15, wherein:
the plurality of first connection pad parts are arranged with a zigzag arrangement along a second direction,
each of the plurality of first connection pad parts includes a first main connection pad and a first sub-connection pad,
the first main connection pad of the plurality of first connection pad parts is arranged side by side along the second direction, and
the second sub-connection pad of the plurality of the first connection pad parts is alternately arranged on one side and the other side of the first main connection pad.

20. A semiconductor package comprising:
an interposer;
a logic die placed on the interposer; and
a high bandwidth memory placed on the interposer,
wherein the high bandwidth memory includes:
a first semiconductor chip and a second semiconductor chip connected to the first semiconductor chip,
wherein the first semiconductor chip includes:
a first semiconductor layer:
a first through electrode penetrating the first semiconductor layer; and
a first connection pad part including a plurality of first connection pads positioned on one surface of the first semiconductor layer and connected to the first through electrode,
wherein the second semiconductor chip includes:
a second semiconductor layer;
a second through electrode penetrating the second semiconductor layer; and
a second connection pad part including a plurality of second connection pads positioned on one surface of the second semiconductor layer and connected to the second through electrode,
wherein the plurality of first connection pads is in contact with the plurality of second connection pads, respectively.
